(19) United States
(12) Patent Application Publication
(10) Pub. No.: US 2017/0186593 A1
(43) Pub. Date: Jun. 29, 2017

(54) CONTOURED TARGET FOR SPUTTERING

(71) Applicant: Seagate Technology LLC, Cupertino, CA (US)

(72) Inventor: Weilu XU, San Jose, CA (US)

(21) Appl. No.: 15/301,346

(22) PCT Filed: Jan. 19, 2015
(86) PCT No.: PCT/US15/11929

§ 371 Date: Sep. 30, 2016

Related U.S. Application Data
(60) Provisional application No. 62/000,981, filed on May 20, 2014.
(60) Provisional application No. 62/074,626, filed on Nov. 3, 2014.

(51) Int. Cl. H01J 37/34; C23C 14/35; G11B 5/851; C23C 14/34

(52) U.S. Cl. CPC H01J 37/3423; C23C 14/3407; C23C 14/35; H01J 37/3405; H01J 37/3429; G11B 5/851

(57) ABSTRACT

Provided herein is an apparatus that includes a body with a top surface and a recess in the top surface. The top surface, excluding the recess, is substantially planar. The recess is confined to an area that is defined by an inner diameter of the top surface of the body.

### RELATED APPLICATIONS

This application claims the benefit of U.S. Provisional Patent Application No. 62/000,981, filed on May 20, 2014, and U.S. Provisional Patent Application No. 62/074,626, filed on Nov. 3, 2014, each of which is incorporated herein by reference.

### BACKGROUND

A hard disk drive (HDD) includes one or more disks for storing digital data. Magnetic recording media may include multiple layers deposited on a substrate. Each layer may be formed by different materials with different properties. One or more of the layers may be deposited using plasma-based physical vapor deposition (PVD). PVD is a method of material deposition through the condensation of a vaporized form of a material onto a surface of the substrate. The vapor of the thin film material is created by physical means from a solid deposition source. An example PVD method is sputter deposition, which deposits material from the collision of ions with a sputtering target. A possible drawback to sputtering is sputter redeposition, which is when vaporized sputtering material falls back onto the sputtering target. Sputter redeposit ion may cause particle build-up on the sputtering target, flaking, arcing, and other associated issues.

### SUMMARY

Provided herein is an apparatus that includes a body with a substantially planar top surface having an inner diameter and an outer diameter, wherein the outer diameter is defined by an edge of the body. The apparatus may also include a recess that is located within an area of the top surface defined by the inner diameter. In some embodiments, a centroid of the recess is located proximate to a center of the top surface of the body. In some embodiments, the thickness of the body in the recess may be less than the thickness of the body at the outer diameter.

Also provided herein is an apparatus that includes a body with a top surface and a recess in the top surface. The top surface, excluding the recess, is substantially planar. In some embodiments, the recess may be confined to an area that is defined by an inner diameter of the top surface of the body. For example, the inner diameter may be approximately 15-50% of a diameter of the top surface. In some embodiments, the recess has a depth in a range of approximately 0.1% to approximately 20% of a thickness of the body at an outer diameter of the body. In some embodiments, the recess is substantially concentric with the inner diameter of the top surface of the body. For example, the recess may have a diameter of approximately 3 inches or less. In some embodiments, the recess is located proximate to a center of the top surface.

Also provided herein is an apparatus that includes a target and a magnetic pack. The target includes a top surface that is substantially planar from an edge of the target to a middle diameter of the target and a recess with a centroid located in proximity to a center of the top surface. The magnetic pack includes one or more magnets that are located underneath the target. In some embodiments, the middle diameter includes a location at 50% or less of the diameter of the target as measured from the edge of the target. The recess may be confined to an area that is defined by an inner diameter of the top surface of the target.

These and other aspects and features may be better understood with reference to the following drawings, description, and appended claims.

### DRAWINGS

FIG. 1A illustrates a plan view of an example sputtering target, according to one aspect.

FIG. 1B illustrates a side view of an example sputtering target, according to one aspect.

FIG. 1C illustrates a cross-sectional view of an example sputtering target, according to one aspect.

FIG. 1D illustrates another cross-sectional view of an example sputtering target, according to one aspect.

FIG. 2 illustrates an example sputtering apparatus using a target, according to one aspect.

FIG. 3 illustrates an example target with a corresponding sputtering region, according to one aspect.

FIG. 4 illustrates example erosion profiles of targets, according to one aspect.

FIG. 5 illustrates a plan view of another example sputtering target, according to one aspect.

### DESCRIPTION

Before some particular embodiments are described in greater detail, it should be understood by persons having ordinary skill in the art that the inventive concepts are not limited to the particular embodiments described and/or illustrated herein, as elements in such embodiments may vary. It should likewise be understood that a particular embodiment described and/or illustrated herein has elements that may be readily separated from the particular embodiment and optionally combined with any of several other embodiments or substituted for elements in any of several other embodiments described herein.

It should also be understood by persons having ordinary skill in the art that the terminology used herein is for the purpose of describing some particular embodiments, and the terminology is not intended to be limiting. Unless indicated otherwise, ordinal numbers (e.g., first, second, third, etc.) are used to distinguish or identify different elements or steps in a group of elements or steps, and such ordinal numbers do not supply a serial or numerical limitation on the elements or steps. For example, “first,” “second,” and “third” elements or steps in a group of elements or steps need not necessarily appear in that order, and the group of elements or steps need not necessarily be limited to three elements or steps. It should also be understood that, unless indicated otherwise, any labels such as “left,” “right,” “front,” “back,” “top,” “bottom,” “forward,” “reverse,” “clockwise,” “counter clockwise,” “up,” “down,” or other similar terms such as “upper,” “lower,” “aft,” “fore,” “vertical,” “horizontal,” “proximal,” “distal,” and the like, are used for convenience and are not intended to imply, for example, any particular fixed location, orientation, or direction. Instead, such labels are used to reflect, for example, relative location, orientation, or directions. It should also be understood that the singular forms of “a,” “an,” and “the” include plural references unless the context clearly dictates otherwise.

Unless defined otherwise, all technical and scientific terms used herein have the same meaning as commonly understood by persons of ordinary skill in the art.

At least one challenge in hard disk manufacturing is reducing disk sputtering defects such as sputtering defects induced by redeposit ion of target material within the inner diameter of the target. Such disk sputtering defects can result in media yield loss and/or reduced drive reliability. Provided herein are targets (e.g., contoured targets) and related methods for reducing disk sputtering defects and/or increasing sputter deposition uniformity, as well as increasing target utilization.

Sputtering deposition results in a substrate or subsequent workpiece coated with a material from a source or “target” co-located with the substrate of workpiece within a sputtering chamber. Sputtering is performed in a vacuum chamber that is filled with one or more gasses selected from reactive gases (e.g., O₂), non-reactive gases, or a combination thereof. In some embodiments, the selected gases are ionized in the vacuum chamber resulting in a plasma. The positive ions of the plasma are then attracted to the target that is biased at a negative potential. When the ions strike the target, the ions transfer energy to the material of the target, causing material from a surface of the target to be ejected. Some of the ejected material adheres to and coats a surface of the substrate or workpiece that may be positioned opposite the target. Since the target does not need to be heated, the technique is used for a wide range of applications. Targets can be composed of pure elements as well as compounds or mixtures.

Approaches to increasing target utilization include increasing magnetic pass through flux (PTF) uniformity. For example, one approach to increase magnetic PTF uniformity is to use a thinner target, such that the magnetic PTF may easily pass through the target leading to a uniform magnetic PTF distribution. However, at a fixed fabrication cost for sputtering targets, a thinner, higher-cost target will result in fewer magnetic recording media than a thicker, lower-cost target.

Targets and related methods provided herein increase sputter deposition uniformity and target utilization by selective target contours (e.g., recesses and/or protrusions), which target contours may be based upon estimated, modeled, or empirically derived target erosion profiles as described herein. While contoured targets may provide gains in magnetic PTF uniformity, and, in turn, target utilization, contoured targets effect increased target utilization through selective target recesses (e.g., regions of decreased target thickness) and/or selective target protrusions for the increased target utilization. While a contoured target may not maintain the thickness of a conventional target over the majority of the contoured target, the amount of sputtering material in the contoured target may be the same or about the same as that in a conventional target, hence having a reasonable cost per target or magnetic recording medium.

Herein, reference to a sputtering target or target may be used interchangeably, as appropriate, and may refer to a body of source material having any suitable material composition or shape (e.g., round, square, annular, etc.) used for sputtering deposition. In some embodiments, the target is substantially circular disc-shaped with a substantially planar top surface.

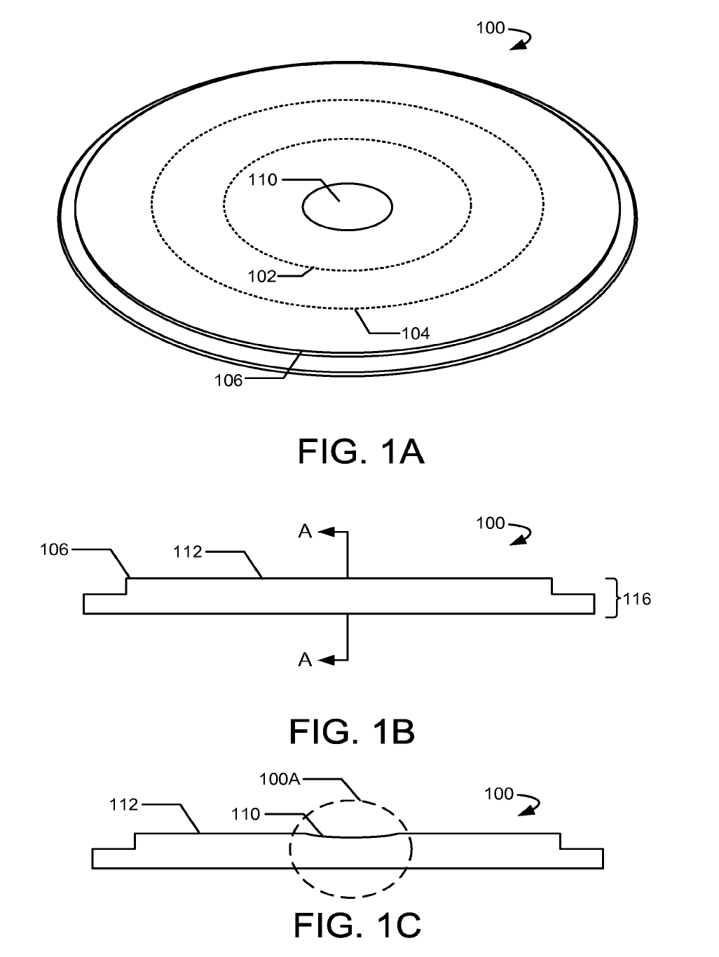

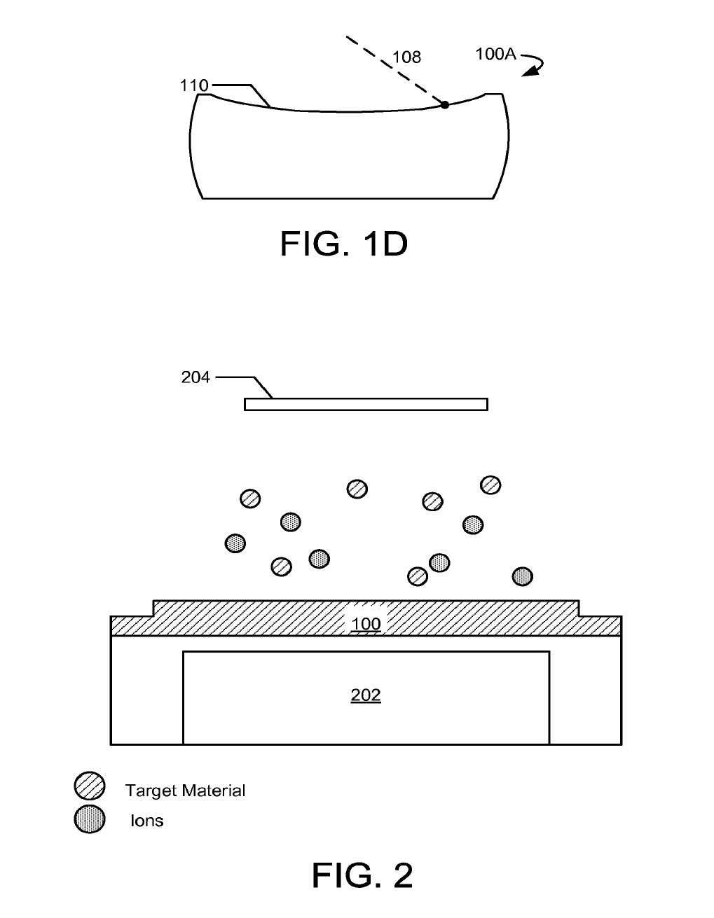

FIG. 1A illustrates a plan view of an example sputtering target (e.g., contoured sputtering target), according to one aspect. Herein, reference to a recess may refer to a concave indention on a surface of the sputtering target. In some embodiments, the recess may be formed by the removal of any suitable amount of material from the surface of the sputtering target such as by machining. Alternatively, the recess may be formed in a molding process. Although this disclosure illustrates and describes sputtering targets with particularly shaped recesses, this disclosure contemplates and includes sputtering targets having any suitably shaped recess (e.g., circular, oval, square, etc.). Furthermore, although this disclosure illustrates and describes a particular configuration of a recess on a top surface of a target, this disclosure contemplates and includes any suitable configuration of one or more recesses in the top surface of the target. For example, multiple recesses 110 may be distributed in the region proximate to the inner diameter, middle diameter, or outer diameter based on the material composition of the target or a magnetic pack underneath the target.

Target 100 includes a body 116 (see FIG. 1B) of source material that may include an inner diameter (ID) region or ID 102, middle diameter (MD) region or MD 104, and outer diameter (OD) region or OD 106. Outer diameter 106 may define a region spanning from an outer edge of a top surface of target 100 to outermost edge of middle diameter 104. In some embodiments, inner diameter 102 of target 100 may define a region spanning from a location proximate to and including the center of target 100 to innermost edge of middle diameter 104. As an example, middle diameter 104 may be between inner diameter 102 and outer diameter 106, including at approximately 50% or more of the diameter of target 100 as measured from the center of target 100. Furthermore, ID 102 of target 100 may include a region approximately 15-50% of a diameter of the top surface of target 100 as measured from the center of the target, including a location at approximately 50% the diameter of MD 104 or at approximately 25% the diameter of OD 106. Target 100 for sputtering may include a recess 110 within inner diameter 102 of target 100. For example, recess 110 may be confined to an area within ID 102 of target 100. In some embodiments, recess 110 may be a circular recess. As described below, such a target 100 may reduce sputtering defects induced by redeposit ion of target material on the target 100.

FIG. 1B illustrates a side view of an example sputtering target. As viewed from OD 106 of target 100, recess 110 may not protrude over the planar top surface 112 of target 100, as illustrated in FIG. 1B. Target 100 may include any suitable material used for sputtering. For example, target 100 may be oxide free. An oxide-free target that includes recess 110 located within inner diameter 102 may substantially reduce or even completely eliminate redeposit ion. In another example, the target may include one or more oxides. Targets that include one or more oxides may easily flake off the surface of a disk and redeposit onto target 100, which in turn may cause arcing splits and voids of target 100. An oxide-containing target that includes recess 110 within the inner diameter substantially reduces or even complete eliminates redisposition, thereby circumventing such arcing splits and voids.

FIG. 1C illustrates a cross-sectional view (Section A-A of FIG. 1B) of an example sputtering target, according to one aspect. Portion 100A of the cross-section view of target 100 includes recess 110 a portion of inner diameter 102. Recess 110 may be created at any stage of target 100. For example, target 100 may be manufactured without recess 110 at inner diameter 102 of target 100, and recess 110 may be subsequently machined into target 100 by removing an appropriate amount of target material. Such manufacturing has the advantage of not requiring retooling at the manufacturing facility. Target material machined out of target 100 may be subsequently recycled.

In some embodiments, top surface 112 of target is planar excluding recess 110, as illustrated in FIG. 1C. In other words, top surface 112 may not have a gradient or slope from OD 106 to the boundary of recess 110. Or the thickness from bottom to top surface 112 of target 100 may be substantially uniform (e.g., 99% uniform) across the top surface. In embodiments, top surface 112 of target 100 may be substantially planar from OD 106 to ID 102. In other embodiments, top surface 112 of target 100 may be substantially planar from OD 106 to MD 104.

FIG. 1D illustrates another cross-sectional view (zoomed in cross-sectional view of portion 100A) of an example sputtering target, according to one aspect. FIG. 1D illustrates a zoomed in view of portion 100A including recess 110 and a portion of inner diameter 102. The dimensions of the recess 110 may vary. For example, recess 110 may be machined having a diameter in the range of approximately 0.5 inches to approximately 4 inches, such as approximately 0.5 inches to approximately 3 inches, including approximately 1 inch to approximately 3 inches and approximately 2 inches to approximately 3 inches. The foregoing recess 110 may also be machined having an arc 108 with a radius of curvature in the range of approximately 0.1 inches to approximately 10 inches, such as approximately 1 inch to approximately 10 inches, including approximately 1 inch to approximately 5 inches and approximately 1 inch to approximately 2.5 inches. The foregoing recess 110 may also be machined having a depth of approximately 0.1% to approximately 40% of the thickness of target 100, such as approximately 1% to approximately 40% of the thickness of target 100, including approximately 1% to approximately 20% of the thickness of target 100 and approximately 1% to approximately 10% of the thickness of target 100.

For example, recess 110 may have a diameter in the range of approximately 1 to 3 inches and a depth of 1% to 20% of the thickness of body 116 at OD 106. For instance, recess 110 may be machined into target 100 with a diameter of about 3 inches and a depth of about 20% of the thickness of target 100. As another example, for target 100 with OD 106 of 6.5 inches, the corresponding arc 108 of recess 110 may have a radius of curvature in the range of approximately 0.5 to 3 inches. The dimensions of recess 110 may be configured based on the material composition of target 100, expected redeposit ion, and/or the expected magnetic pass through flux (PTF) of target 100 during sputtering. As described below, the magnetic PTF may be a function of a configuration of an underlying magnetic pack in the sputtering process. In some embodiments, a centroid of recess 110 may be substantially located at a center of the surface of target 100. In some embodiments, the radius of curvature of arc 108 may be configured based on the material composition of target 100, expected redeposit ion, and/or the expected magnetic PTF over various portions of target 100. For example, a higher radius of curvature of arc 108 may result in the magnetic PTF being enhanced over a larger area of top surface 112 of target 100.

FIG. 2 illustrates an example sputtering apparatus using a target, according to one aspect. As described above, sputtering is carried out in a vacuum chamber that is filled with one or more gases (e.g., argon, oxygen, etc.). Target 100, as described previously in FIGS. 1A-1D, may be used to deposit material on a disk 204. Disk 204 is positioned over or opposite target 100, and target 100 may overlie a magnet pack 202. Sputtering deposition involves ejecting material from target 100 onto disk 204, such as a disk for magnetic recording media. For example, disk 204 may be fabricated from aluminum coated with nickel phosphorous, glass, or glass-containing materials (e.g., glass-ceramics), ceramics (e.g., crystalline ceramics), partly crystalline ceramics, or amorphous ceramics, etc. Disk 204 may be biased to a positive potential and target 100 may be biased to a negative potential, thereby establishing an electric field between disk 204 and target 100.

During the sputtering process, electrons are introduced into the vacuum chamber and these electrons strike atoms of the gas, forming positively charged ions. Magnetic pack 202 creates magnetic fields that confine the electrons to the sputtering zone, thereby increasing the number of positively charged ions and preventing the electrons from striking disk 204. The positively charged ions are attracted by the negative bias of target 100. The ions strike the surface of target 100, releasing target material that is neutrally charged and unaffected by the magnetic field of magnetic pack 202. In some embodiments, the sputtering apparatus may include a shield that directs the target material sputtered from target 100 through an aperture and onto disk 204.

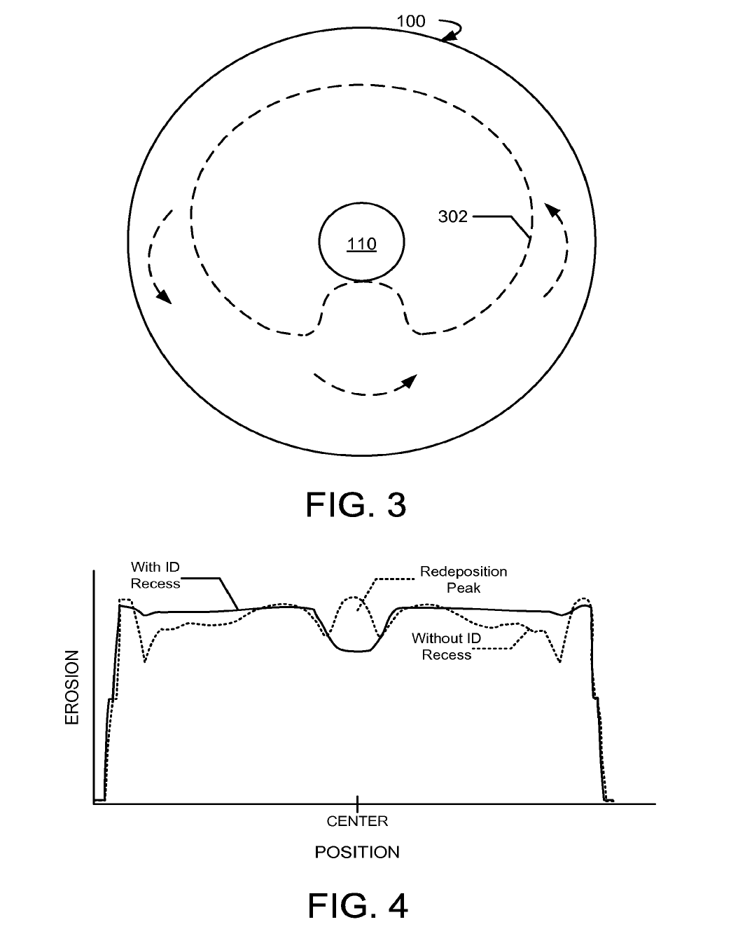

FIG. 3 illustrates an example target with a corresponding sputtering region, according to one aspect. A form of sputter deposition is magnetron sputtering that uses a configuration including a magnet pack that is placed underneath target 100 to confine the plasma within a sputtering region. Target 100, as described previously in FIGS. 1A-1D, may be used in conjunction with a magnetron that utilizes electric and magnetic fields to confine charged plasma particles close to the surface of target 100. A magnetic pack may be placed behind the target to help confine the plasma used in sputtering and enhance the sputtering process. In some embodiments, the magnetic pack used in conjunction with target 100 may include one or more magnets. As an example, the magnets may be fabricated using neodymium, samarium-cobalt, a ceramic, alnico (iron alloys comprising aluminum, nickel, and cobalt), stainless steel, or steel. In a magnetic field, electrons follow helical paths around magnetic field lines, thereby undergoing more ionizing collisions with the selected gases near the surface of target 100 than would otherwise occur.

The configuration of the magnets of the magnetic pack may lead to different rates of erosion at each of the ID 102, MD 104, and OD 106 of the target 100, thereby resulting in poor material utilization of target 100. For example, the configuration of the magnets of the magnetic pack may lead to erosion of the target ID 102 at a faster rate than the MD 104 and/or the OD 106 of target 100. Material utilization is the percentage of the total material of target 100 that is utilized for deposition of target material on the substrates before target 100 needs to be replaced due to a failure or depletion of material. In some embodiments, the erosion profile of target 100 may be estimated, modeled, or empirically derived from the configuration of the magnetics of the underlying magnetic pack. Based on the estimated, modeled, or empirically derived erosion profile, the amount or thickness of material of target 100 may be adjusted or modified, optionally iteratively, from a completely planar surface or a contoured target surface, as the case may be. For example, to minimize target trench or erosion tracks, or to increase target utilization over the top surface of the target at end of target life, the thickness may be selectively increased in any areas of the target that may have increased erosion relative to the erosion at other areas of target 100. For example, erosion at the OD 106 of target 100 may be higher than the rest of the top surface due to leakage of the magnetic field around the edge of the OD 106. In some embodiments, the thickness at the OD 106 of target 100 may be increased to compensate for the enhanced magnetic PTF at the OD relative to the magnetic PTF at the MD and/or ID. As another example, the thickness may be selectively reduced in any areas of the target that may have decreased erosion relative to the erosion at other areas of target 100. For example, erosion at the ID 102 of target 100 may be less than the rest of the top surface. In some embodiments, the thickness at the ID 102 of target 100 may be reduced relative to the MD and/or OD to compensate for the decreased erosion. As described herein above, there may be any suitable configuration of one or more recesses (e.g., central recess and/or annular recesses) in the top surface of the target. Likewise, there may be any suitable configuration of one or more annular protrusions (e.g., regions of increased thickness) of the top surface of the target. For example, multiple recesses and/or protrusions may be about the target (e.g., contoured target), distributed in the regions proximate to the inner diameter, middle diameter, or outer diameter based on the material composition of the target or a magnetic pack underneath the target.

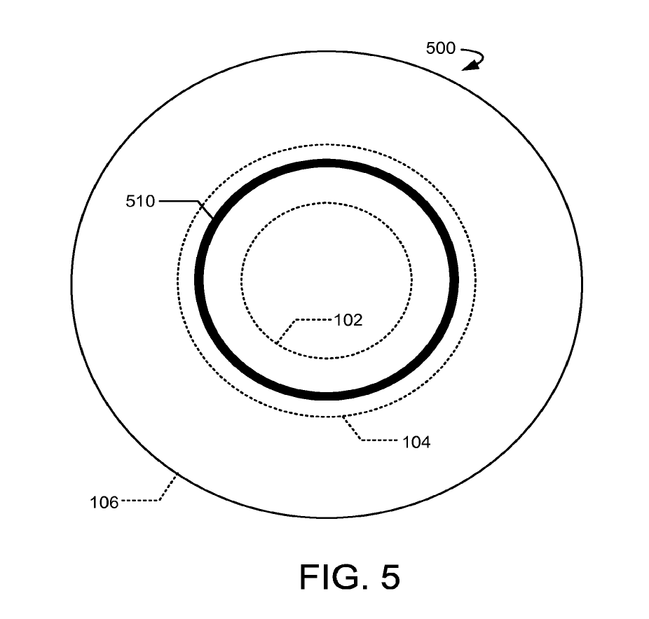

Any regions of increased thickness about the target 100 may be machined or molded in the shape of an annular protrusion about the center of the target 100. (See FIG. 5 for an analogous annular recess 510.) For example, the annular protrusion may be machined having a annular thickness (e.g., difference between outer radius and inner radius of the annular protrusion) in the range of approximately 0.1 inches to approximately 4 inches, such as approximately 0.5 inches to approximately 3 inches, including approximately 0.5 inches to approximately 1.5 inches and approximately 0.75 inches to approximately 1.25 inches. The foregoing annular protrusion may also be machined having an arc with a radius of curvature in the range of approximately 0.1 inches to approximately 10 inches, such as approximately 1 inch to approximately 10 inches, including approximately 1 inch to approximately 5 inches and approximately 1 inch to approximately 2.5 inches. The foregoing annular protrusion may also be machined having a height above the surface of the target of approximately 0.1% to approximately 40% of the thickness of target 100, such as approximately 1% to approximately 40% of the thickness of target 100, including approximately 1% to approximately 20% of the thickness of target 100 and approximately 1% to approximately 10% of the thickness of target 100.

Any regions of decreased thickness about the target 100 (other than recess 110) may be machined or molded in the shape of an annular recess about the center of the target 100. (See FIG. 5 for annular recess 510.) For example, the annular recess may be machined having a annular thickness (e.g., difference between outer radius and inner radius of the annular recess) in the range of approximately 0.1 inches to approximately 4 inches, such as approximately 0.5 inches to approximately 3 inches, including approximately 0.5 inches to approximately 1.5 inches and approximately 0.75 inches to approximately 1.25 inches. The foregoing annular recess may also be machined having an arc with a radius of curvature in the range of approximately 0.1 inches to approximately 10 inches, such as approximately 1 inch to approximately 10 inches, including approximately 1 inch to approximately 5 inches and approximately 1 inch to approximately 2.5 inches. The foregoing annular recess may also be machined having a depth below the surface of the target of approximately 0.1% to approximately 40% of the thickness of target 100, such as approximately 1% to approximately 40% of the thickness of target 100, including approximately 1% to approximately 20% of the thickness of target 100 and approximately 1% to approximately 10% of the thickness of target 100.

During sputtering deposition, a sputtering region 302 may be defined by the magnetic flux in the area between the magnetic north and corresponding south poles of the magnets of the magnetic pack. The magnetic field of sputtering region 302 is superimposed upon the electric field between the disk and target 100, thereby enhancing the sputtering process. The magnetic field of sputtering zone 302 traps electrons and by applying a magnetomotive force directs the electrons toward the surface of the negatively biased target 100. The magnetic field profile of sputtering region 302 on the surface of target 10( )defines the path of the positively charged ions and results in the erosion pattern or “track” on target 100 as material is sputtered from target 100. Magnetic PTF may refer to the strength of the magnetic field at the top surface of target 100 resulting from the magnetic field provided by the magnetic pack. In general the higher the magnetic strength of the magnetic pack, the higher the magnetic PTF on the top surface of target 100.

The magnetic pack underneath target 100 may be rotated (e.g., counterclockwise, as shown in FIG. 3) about the center of target 100, which in turn rotates sputtering region 302 over the top surface of target 100. In the case where sputtering region 302 is located on the center of target 100, sputtering region 302 would have a stationary portion at the center of that would quickly erode the material at the center of target 100. For this reason, sputtering region 302 may be located such that sputtering region 302 is offset from the centroid of target 100, as illustrated in FIG. 3. Rotation of sputtering region 302 results in a more uniform depletion of the material of target 100.

In some embodiments, the magnet pack may be configured to customize or shape the sputtering zone 302 depending on the material composition of target 100. The magnetic PTF of sputtering zone 302 should be sufficiently high to ignite and sustain the plasma in the vacuum chamber. Targets with a uniformly planar top surface may have a magnetic PTF distribution that is higher at the edges than at the center of the target as the magnetic field of the magnetic pack flows around the edges of the target. The reduction of magnetic PTF at the center of the target may be compensated by having a recess that reduces the thickness of material blocking the magnetic PTF at the inner diameter of target 100, thereby providing a more uniform magnetic PTF distribution compared to the edges of target 100 and in turn a more uniform erosion pattern on target 100 as well as higher target utilization. Furthermore, the dimensions of the recess of target 100 may be determined based on the material composition of target 100 and the required magnetic PTF for sputtering. For example, the recess may be configured such that the magnetic PTF over the recess is within 10% of the magnetic PTF flux over the middle diameter.

FIG. 4 illustrates example erosion profiles of targets, according to one aspect. In some embodiments, the target used to sputter a magnetic recording layer may at least one magnetic element, such as cobalt (Co), nickel (Ni), and/or iron (Fe). The target may also include one or more non-magnetic metallic element, such as, for example, chromium (Cr), tantalum (Ta), tungsten (W), niobium (Nb), ruthenium (Ru), iridium (Ir), palladium (Pd), platinum (Pt), rhodium (Rh), gold (Au), or silver (Ag) may be alloyed with the magnetic material, as well as one or more oxides (e.g., an oxide of silicon). In some embodiments, targets used for sputtering magnetic material may have a diameter of 6.5 inches, a material thickness of 2.5 inches from the top surface to the bottom surface, and 1 inch diameter recess. In some embodiments, targets used for sputtering magnetic material may have a diameter of 6.5 inches, a material thickness of 2.5 inches from the top surface to the bottom surface, and 3 inch diameter recess. In some embodiments, targets for hard magnetic layers may be made of a uniform mixture of cobalt, chrome, platinum, and oxides (e.g., an oxide of silicon). Oxides may be used in perpendicular magnetic recording media to segregate grain boundaries.

Erosion profiles as a function of position for a target with a recess, as described in FIGS. 1A-1D, and a target without a recess are illustrated in FIG. 4. In the case of targets that include magnetic materials, the strength of the high intrinsic permeability of the magnetic material effectively shields or shunts the magnetic field from the magnetic pack underneath the target and reduces the magnetic PTF on the target surface. For this reason, the magnetic field of the magnetic pack may need to be significantly increased to generate sufficient magnetic PTF to properly sputter these materials. The erosion profiles illustrated in FIG. 4 may be measured along a cross-section that includes the inner diameter as illustrated in FIG. 1C. A target without a recess may use a modified magnetic pack to increase the magnetic PTF at the inner diameter of the target, which in turn may lead to faster material depletion at the ID and one or more material redeposit ion peaks on the surface of the disk. Increased material deposition of material with a high percentage of oxides may lead to increased redeposit ion of target material onto the target because oxides self-segregate themselves from the target material causing flaking.

Redeposition of material onto the target may cause arcing and other issues related to the target. In some magnetic pack configurations, more material from the target may be depleted from the inner diameter, such that material deposited on the disk is thicker in the center of the disk and some of the material deposited on the disk may redeposit on the inner diameter of the target. As illustrated in FIG. 4, targets without a recess show significant material redeposit ion at the inner diameter near the center of the target. In contrast, the target with a recess does not show any significant material deposition. In some embodiments, the hard magnetic layer of magnetic recording media may fabricated using a target that includes a relative high percentage of oxide (e.g., 40% oxide). A target with a recess within the inner diameter may be used with a mixture of high percentage oxides target without significant redeposit ion, as illustrated in FIG. 4. Targets with a recess provided herein are expected to have substantial impact with respect to cost reduction for sputtering-related articles such as disks of magnetic recording media for hard disk drives, as well as quality control.

FIG. 5 illustrates a plan view of another example sputtering target (e.g., contoured sputtering target), according to one aspect. As described above, outer diameter 106 of target 500 may define a region spanning from an outer edge of a top surface of target 500 to outermost edge of middle diameter 104. ID 102 of target 500 may define a region spanning from a location proximate to and including the center of target 500 to innermost edge of middle diameter 104. For example, ID 102 of target 500 may include a region approximately 15-50% of a diameter of the top surface of target 500 as measured from the center of the target, including a location at approximately 50% the diameter of MD 104 or at approximately 25% the diameter of OD 106. Additionally, MD 104 may be between inner diameter 102 and outer diameter 106, including at approximately 50% or more of the diameter of target 500 as measured from the center of target 500. More uniform magnetic PTF may be achieved by enhancing the magnetic PTF over the area of ID 106 or MD 204. In some embodiments, recess 510 may include the area defined by ID 106 of target 500. In other embodiments, recess 510 may include area defined by the ID of target 500 and a portion of the area defined by MD 104. For example, for target 500 with a diameter of 6.5 inches, recess 510 may have a diameter of 3.5 inches and a depth of 0.05 inches. As described above, the dimensions of recess 510 of target 500 may be determined based on the material composition of target 500, the configuration of the magnetics of the underlying magnetic pack, or the required magnetic PTF for sputtering.

As such, provided herein is an apparatus that includes a body with a substantially planar top surface having an inner diameter and an outer diameter, wherein the outer diameter is defined by an edge of the body. The top surface is substantially planar from the outer diameter to a middle diameter. The middle diameter may include a diameter that is approximately half of the outermost diameter of an edge of the body. The apparatus may also include a recess that is located within an area of the top surface defined by the inner diameter. In some embodiments, a centroid of the recess is located proximate to a center of the top surface of the body. In some embodiments, the thickness of the body in the recess may be less than the thickness of the body at the outer diameter. For example, the recess may have a depth in a range of approximately 1% to approximately 20% of the thickness of the body at the outer diameter. In some embodiments, the recess has a radius of curvature in a range of approximately 0.1 inches to approximately 10 inches. For example, the body may have a diameter of 6.5 inches and the recess may have a diameter of approximately 1 inch. In some embodiments, the body includes cobalt and an oxide.

Also provided herein is an apparatus that includes a body with a top surface and a recess in the top surface. The top surface, excluding the recess, is substantially planar. In some embodiments, the recess may be confined to an area that is defined by an inner diameter of the top surface of the body. For example, the inner diameter may be approximately 15-50% of a diameter of the top surface. In some embodiments, the recess has a depth in a range of approximately 0.1% to approximately 20% of a thickness of the body at an outer diameter of the body. In some embodiments, the recess is substantially concentric with the inner diameter of the top surface of the body. For example, the recess may have a diameter of approximately 1 inch. In some embodiments, the recess is located proximate to a center of the top surface.

Also provided herein is an apparatus that includes a contoured target and a magnetic pack. The target includes a top surface that is substantially planar from an edge of the target to a middle diameter of the target and a recess with a centroid located in proximity to a center of the top surface. The magnetic pack includes one or more magnets located underneath the target. In some embodiments, the middle diameter includes a location at 50% or less of the diameter of the target as measured from the edge of the target. The recess may be confined to an area that is defined by an inner diameter of the top surface of the target. In some embodiments, the recess has a diameter in a range of approximately 0.5 inches to approximately 2 inches. In other embodiments, the recess has a radius of curvature in a range of approximately 0.1 inches to approximately 10 inches. In some embodiments, the recess has a depth in a range of approximately 1% to approximately 20% of a thickness of the target at an outer diameter of the target. The recess may be configured such that a magnetic pass through flux (PTF) over the recess is within 10% of the magnetic PTF flux over the middle diameter. The magnetic PTF is generated by the one or more magnets of the magnetic pack.

Also provided herein is a method, comprising ionizing one or more gases in a chamber to produce a plasma comprising ions of the one or more gases; electrically biasing a contoured target in the chamber to attract the ions; and sputtering target material dislodged from the contoured target by the ions onto a workpiece in the chamber, wherein the contoured target is configured to increase target utilization or increase sputter deposition uniformity on the workpiece, as compared to a non-contoured target. In some embodiments, the contoured target is operable to increase target utilization by at least approximately 1-2%, as compared to a non-contoured target. In some embodiments, the contoured target comprises a recess in a center of a top surface of the contoured target, one or more annular recesses in the top surface of the contoured target, one or more annular protrusions of the top surface of the contoured target, or a combination thereof. In some embodiments, the contoured target comprises a recess in a center of a top surface of the contoured target configured to reduce redeposit ion of the target material at the center of the contoured target, as compared to a non-contoured target without the recess. In some embodiments, the contoured target is approximately 6.5 inches in diameter, the recess is approximately 1 inch to approximately 4 inches in diameter, and a thickness of the contoured target at the center of the contoured target is approximately 80% to approximately 99.9% a thickness of the contoured target at an outer diameter of the contoured target. In some embodiments, the method further comprises contouring a non-contoured target or previously contoured target based upon one or more erosion profiles for the non-contoured target or previously contoured target to create the contoured target. In some embodiments, the contouring comprises adding one or more recesses in low erosion areas of the non-contoured target or previously contoured target, adding one or more protrusions in high erosion areas of the non-contoured target or previously contoured target, or a combination thereof.

While some particular embodiments have been described, and while these particular embodiments have been described in considerable detail, it is not the intention of the applicant(s) to restrict or in any way limit the scope of the inventive concepts to such detail. Additional adaptations and/or modifications of the presented embodiments may readily appear to persons having ordinary skill in the art, and the inventive concepts may encompass these adaptations and/or modifications. Accordingly, departures may be made from the foregoing embodiments without departing from the scope of the inventive concepts, which scope is limited only by the following claims when appropriately construed.

What is claimed is:

1. An apparatus, comprising:
a body with a substantially planar top surface having an inner diameter, a middle diameter and an outer diameter,
wherein the top surface is substantially planar from the outer diameter to the middle diameter, and
wherein the outer diameter is defined by an edge of the body; and a recess located within an area of the top surface defined by the inner diameter,
wherein a thickness of the body in the recess is less than a thickness of the body at the outer diameter.

2. The apparatus of claim 1,
wherein a centroid of the recess is located proximate to a center of the top surface of the body.

3. The apparatus of claim 2,
wherein the thickness of the body in the recess at the centroid is in a range of approximately 80% to 99.9% the thickness of the body at the outer diameter, as measured from a bottom surface of the body to the top surface of the body.

4. (canceled)

5. The apparatus of claim 4,
wherein the middle diameter includes a diameter that is approximately half of the outermost diameter of an edge of the body.

6. The apparatus of claim 5,
wherein the recess has a depth in a range of approximately 0.1% to approximately 20% of the thickness of the body at the outer diameter.

7. The apparatus of claim 1,
wherein the recess has a radius of curvature in a range of approximately 0.1 inches to approximately 10 inches.

8. The apparatus of claim 1, wherein:
the body has a diameter of 6.5 inches; and
the recess has a diameter of approximately 1 inch.

9. The apparatus of claim 1,
wherein the body comprises cobalt and an oxide.

10. An apparatus, comprising:
a body with a top surface; and
a recess in the top surface,
wherein the top surface excluding the recess is substantially planar, and
wherein the recess is confined to an area that is defined by an inner diameter of the top surface of the body.

11. The apparatus of claim 10,
wherein the inner diameter is approximately 15-50% of a diameter of the top surface.

12. The apparatus of claim 10,
wherein the recess has a depth in a range of approximately 1% to approximately 20% of a thickness of the body at an outer diameter of the body.

13. The apparatus of claim 10,
wherein the recess is substantially concentric with the inner diameter of the top surface of the body.

14. The apparatus of claim 10,
wherein the recess has a diameter of approximately 1 inch.

15. The apparatus of claim 10,
wherein the recess is located proximate to a center of the top surface.

16. An apparatus, comprising:
a contoured target comprising:
a top surface that is substantially planar from an edge of the target to a middle diameter of the target,
wherein the middle diameter includes a location at 50% or less of the diameter of the target as measured from the edge of the target; and
a recess with a centroid located in proximity to a center of the top surface; and
a magnetic pack comprising one or more magnets located underneath the target.

17. The apparatus of claim 16,
wherein the recess is confined to an area that is defined by an inner diameter of the top surface of the target.

18. The apparatus of claim 16,
wherein the recess has a diameter in a range of approximately 0.5 inches to approximately 2 inches.

19. The apparatus of claim 16,
wherein the recess has a radius of curvature in a range of approximately 0.1 inches to approximately 10 inches.

20. The apparatus of claim 16,
wherein the recess is configured such that a magnetic pass through flux (PTF) over the recess is within 10% of the magnetic PTF over the middle diameter, and wherein the magnetic PTF is generated by the one or more magnets.

21. The apparatus of claim 16,
wherein the recess has a depth in a range of approximately 1% to approximately 20% of a thickness of the target at an outer diameter of the target.

22. A method, comprising:
ionizing one or more gases in a chamber to produce a plasma comprising ions of the one or more gases;
electrically biasing a contoured target in the chamber to attract the ions,
wherein the contoured target comprises a recess in a center of a top surface of the contoured target, the recess configured to substantially eliminate redeposition of the target material at the center of the contoured target; and
sputtering target material dislodged from the contoured target by the ions onto a workpiece in the chamber.

23. The method of claim 22,
wherein the contoured target is operable to increase target utilization by at least approximately 1-2%, as compared to a non-contoured target.

24. The method of claim 22,
wherein the contoured target comprises a recess in a center of a top surface of the contoured target, one or more annular recesses in the top surface of the contoured target, one or more annular protrusions of the top surface of the contoured target, or a combination thereof.

25. (canceled)

26. The method of claim 22,
wherein the contoured target is approximately 6.5 inches in diameter, wherein the recess is approximately 1 inch to approximately 4 inches in diameter, and
wherein a thickness of the contoured target at the center of the contoured target is approximately 80% to approximately 99.9% a thickness of the contoured target at an outer diameter of the contoured target.

27. The method of claim 22, further comprising
contouring a non-contoured target or previously contoured target based upon one or more erosion profiles for the non-contoured target or previously contoured target to create the contoured target.

28. The method of claim 27,
wherein the contouring comprises adding one or more recesses in low erosion areas of the non-contoured target or previously contoured target, adding one or more protrusions in high erosion areas of the non-contoured target or previously contoured target, or a combination thereof.
